(19) United States
(12) Patent Application Publication
(10) Pub. No.: US 2024/0227123 A1
(43) Pub. Date: Jul. 11, 2024

(54) MULTI-NOZZLE FOR SUPPLYING CMP SLURRY AND CMP EQUIPMENT INCLUDING THE SAME

(71) Applicants: SK Hynix Inc., Icheon-si (KR); Joungwoo Nano-Technology Co., Ltd., Suwon-si (KR)

(72) Inventors: Young Jo HA, Suwon-si (KR); Jong Yeol PARK, Icheon-si (KR); Jun Ho BAN, Icheon-si (KR); Yong Seok OH, Icheon-si (KR)

(21) Appl. No.: 18/402,891

(22) Filed: Jan. 3, 2024

(30) Foreign Application Priority Data
Jan. 11, 2023 (KR) 10-2023-0004253

(51) Int. Cl. B24B 57/02

(52) U.S. Cl. CPC B24B 57/02

(57) ABSTRACT

The present invention relates to a multi-nozzle for supplying CMP slurry. An exemplary embodiment of the present invention drops the slurry from the center of a pad to the outside through a plurality of spray nozzles, thereby increasing the efficiency of a planarization process by evenly spreading the slurry over the entire pad and reducing costs by minimizing the amount of slurry wasted.

### TECHNICAL FIELD

The present invention relates to a multi-nozzle for supplying CMP slurry, comprising a fitting unit 100 connected to supply a slurry stored in a slurry supply unit and a deionized water stored in a deionized water supply unit, a buffer tank unit 200 coupled to the tip of the fitting unit 100, which uniformly distributes the slurry or deionized water and discharges it through a plurality of lines, a plurality of tubes 300 connected to the tip of the buffer tank unit 200, and a spray nozzle unit 400 connected to each of the tubes 300 to supply the slurry or deionized water to a polishing pad.

### BACKGROUND

In general, the chemical mechanical polishing (CMP) process is a semiconductor manufacturing process that flattens the surface of a silicon wafer. As shown in FIG. 1, the planarization process refers to a process in which the surface of the wafer is brought into close contact with a pad 10, then the slurry is dropped through a nozzle device 50 formed on a slurry supply arm 40, and the slurry is injected between the wafer and the pad to flatten the surface of the wafer by rotational and moving forces, while the wafer is supported on a head 20 provided at the tip of a conditioner 30, which has the function of preventing scratches on the surface of the wafer.

Meanwhile, the existing device that supplies slurry onto the pad sprays the slurry through a single nozzle, so the slurry is not evenly spread over the entire pad, which reduces the efficiency of the planarization process and causes a rise in manufacturing costs due to the large amount of slurry being discarded.

### RELATED ART DOCUMENTS

### Patent Document

Patent Document 1: Korea Patent Publication No. 10-1681679

### SUMMARY

The present invention is devised to solve the above-mentioned problems. The purpose of the present invention is to drop slurry from the center of the pad to the outside through a plurality of spray nozzles, such that the slurry is evenly spread over the entire pad, increasing the efficiency of the planarization process and reducing costs by minimizing the amount of slurry wasted.

In order to solve the above problems, the multi-nozzle for supplying CMP slurry according to the present invention includes a fitting unit 100 connected to supply a slurry stored in a slurry supply unit and a deionized water stored in a deionized water supply unit, a buffer tank unit 200 coupled to the tip of the fitting unit 100, which uniformly distributes the slurry or deionized water and discharges it through a plurality of lines, a plurality of tubes 300 connected to the tip of the buffer tank unit 200, and a spray nozzle unit 400 connected to each of the tubes 300 to supply the slurry or deionized water to a polishing pad.

Moreover, the fitting unit 100 includes a slurry supply line 110 through which the slurry is supplied and a deionized water supply line 120 through which the deionized water is supplied, and a first discharge line 130 connected to the slurry supply line 110 and the deionized water supply line 120.

Moreover, the deionized water supply line 120 includes a backflow prevention check valve 140 to prevent the slurry supplied through the slurry supply line 110 from flowing back toward the deionized water supply line 120.

Moreover, the buffer tank unit 200 includes a cover member 210 with a space formed on the inside and a distribution housing 220 that is seated in the space of the cover member 210 and distributes the slurry or deionized water.

Moreover, the distribution housing 220 includes a cone-shaped fluid inlet groove 221 at the center of the end, a plurality of fluid transfer holes 222 formed around the surface of the fluid inlet groove 221, and a plurality of second discharge lines 223 connected to each of the fluid transfer holes 222.

Moreover, between the fitting unit 100 and the distribution housing 220, in the process of supplying the slurry to the distribution housing 220 through the slurry supply line 110 and the first discharge line 130, includes a mesh plate 230 to spread the slurry or filter out foreign substances contained in the slurry.

Moreover, the second discharge line 223 is arranged in a circular shape around the horizontal axis of the distribution housing 220.

Moreover, the tube 300 is connected to the second discharge line 223, and the tube 300 and the second discharge line 223 are connected through a connection nipple 240.

Moreover, the spray nozzle unit 400 includes a connection plate 410 coupled to the buffer tank unit 200, a base plate 420 coupled to the tip of the connection plate 410, a nozzle block 430 whose angle is adjusted according to the operator's operation, and a spray nozzle 440 coupled to the nozzle block 430 and connected to the tube 300.

Moreover, the nozzle block 430 includes a hinge portion 431 formed on the base plate 420, a rotation block member 432 that is coupled to the hinge portion 431 and rotates around the hinge portion 431, and is formed with a plurality of angle adjustment holes 433 and a plurality of spray nozzle seating holes 434, respectively, and a fixing member 435 capable of adjusting the angle of the rotation block member 432 according to the angle adjustment hole 433 that is rotatably formed and inserted into the base plate 420.

Moreover, the spray nozzle 440 includes a fitting head 441 into which the tube 300 is inserted and a nozzle tube 442 through which the slurry or deionized water is sprayed.

Moreover, the spray nozzle 440 is formed in eight pieces.

Moreover, on the side of the base plate 420 a bumper groove 421 is recessed, and on the side of the rotation block member 432, in the process of rotating the rotation block member 432 around the hinge portion 431, when the maximum rotation of the rotation block member 432 is achieved, a bumper stopper 436 is formed to be inserted into the bumper groove 421.

Moreover, at the end of the hinge portion 431 a lifting protrusion 431a is formed protruding, and in the base plate 420 a lifting guide groove 422 is perforated such that the lifting protrusion 431a is inserted and the hinge portion 431 is raised or lowered.

Moreover, on the outer surface of the tube 300 a diamond-shaped fixing seal member 310 is provided, and on the inner surface of the fitting head 441 a diamond-shaped coupling groove 443 is formed such that the fixing seal member 310 is inserted and fixed.

Moreover, at the end of the fitting unit 100, a slurry mixing unit 500 is connected to the slurry supply line 110 to mix and supply slurries with different components.

Moreover, a pressure sensor is provided in a supply tube connected to a slurry supply unit, and when any one of the fitting unit 100, the buffer tank unit 200, the tube 300, or the spray nozzle unit 400 is clogged due to hardened slurry or foreign substances, the pressure sensor detects pressure deviation and transmits a detection signal to a control room.

As described above, according to the present invention, the slurry is evenly applied on the pad, thereby increasing the efficiency of the planarization process and providing the advantage of cost reduction.

Moreover, due to the structure of the mesh plate with a mesh net, the slurry spreads, enters and moves into each discharge line, thereby guiding the uniform spraying of the slurry from each spray nozzle and filtering out foreign substances that may be present in the slurry to prevent clogging.

Moreover, there is an advantage that efficient slurry supply is possible by determining and arranging the number of spray nozzles in consideration of the cross-sectional area of the pad.

Moreover, since the angle of the spray nozzle on the plane is adjustable, there is an advantage that the position of the spray nozzle can be adjusted by being compatible with the equipment specifications of each CMP equipment company.

### BRIEF DESCRIPTION OF THE DRAWINGS

FIG. 1 is an exemplary embodiment showing planarization through the existing CMP process.

FIG. 2 is a perspective view showing the overall appearance of a multi-nozzle for supplying CMP slurry according to a preferred embodiment of the present invention.

FIG. 3 is a perspective view showing a fitting unit in the configuration of a multi-nozzle for supplying CMP slurry according to a preferred embodiment of the present invention.

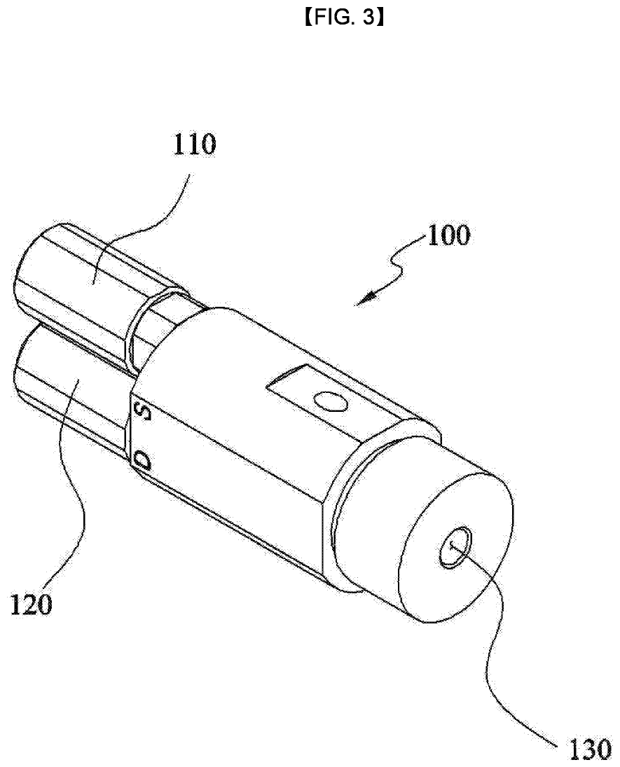

FIG. 4 is a cross-sectional view showing a cross-section of a fitting unit in the configuration of a multi-nozzle for supplying CMP slurry according to a preferred embodiment of the present invention.

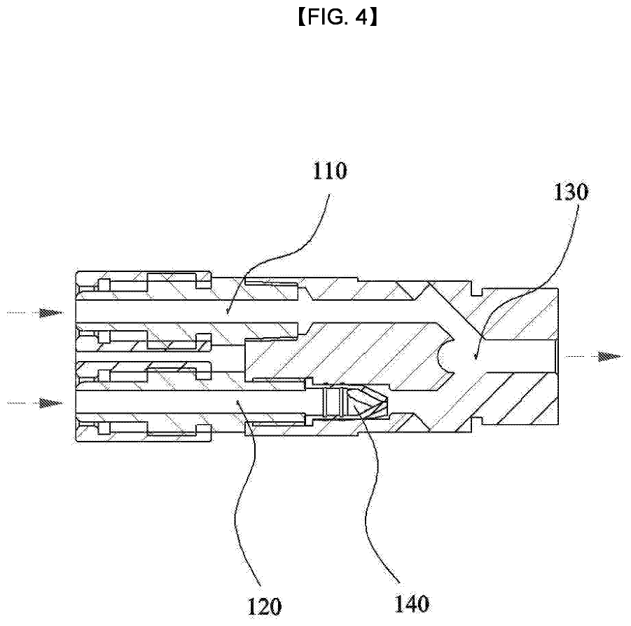

FIG. 5 is a perspective view showing the overall appearance of the buffer tank unit and tube in the configuration of the multi-nozzle for supplying CMP slurry according to a preferred embodiment of the present invention.

FIG. 6 is an exploded perspective view showing the disassembled buffer tank unit in the configuration of the multi-nozzle for supplying CMP slurry according to a preferred embodiment of the present invention.

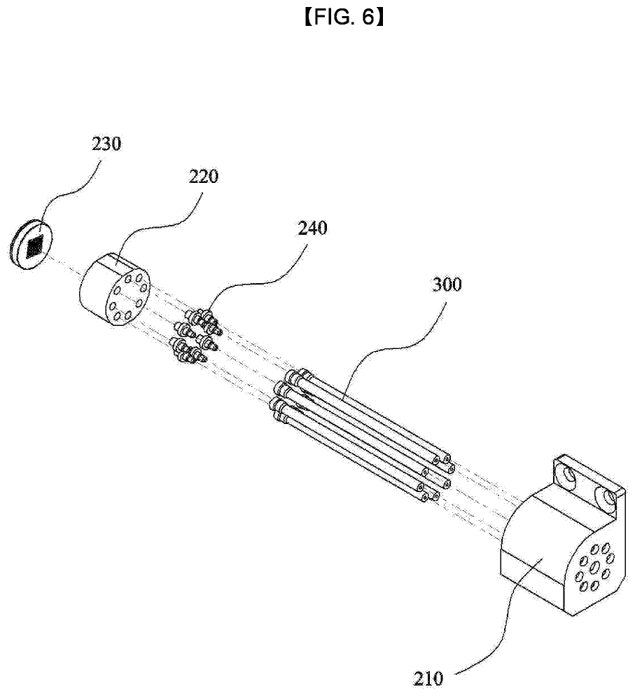

FIGS. 7(a) and 7(b) are a cross-sectional perspective view showing the distribution housing in the configuration of the multi-nozzle for supplying CMP slurry according to a preferred embodiment of the present invention.

FIG. 8 is a cross-sectional view and an enlarged view showing the cross-section of the buffer tank unit and tube in the configuration of the multi-nozzle for supplying CMP slurry according to a preferred embodiment of the present invention.

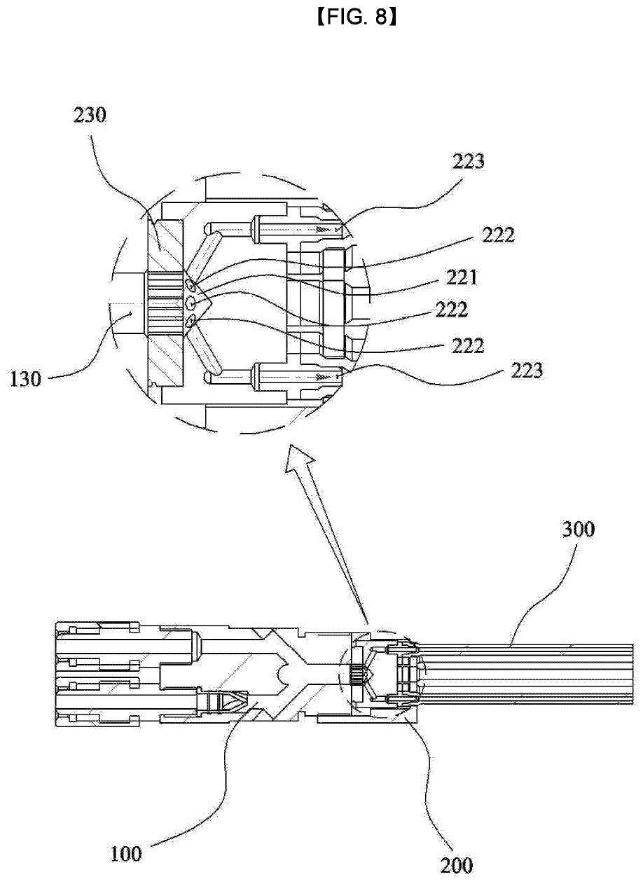

FIG. 9 is a perspective view showing the overall appearance of the spray nozzle unit in the configuration of the multi-nozzle for supplying CMP slurry according to a preferred embodiment of the present invention.

FIG. 10 is an exploded perspective view showing the disassembled spray nozzle unit of the multi-nozzle for supplying CMP slurry according to a preferred embodiment of the present invention.

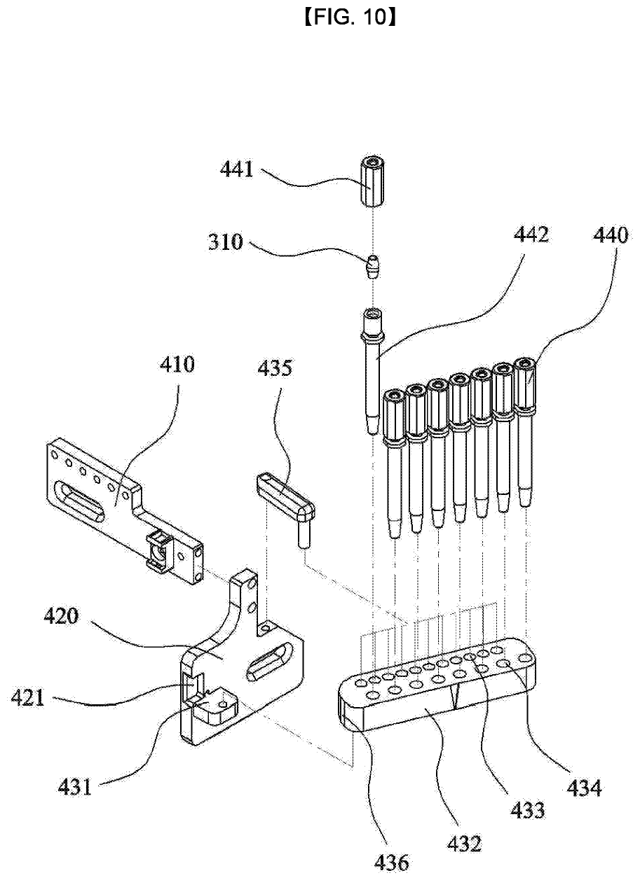

FIGS. 11(a) and 11(b) show an exemplary embodiment showing the rotation of the rotation block member of the spray nozzle unit in the configuration of the multi-nozzle for supplying CMP slurry according to a preferred embodiment of the present invention.

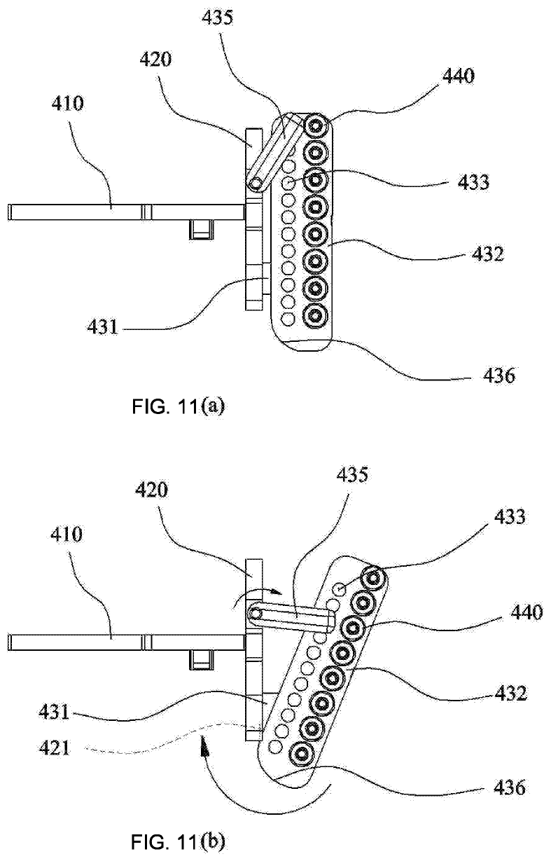

FIGS. 12(a) and 12(b) show an exemplary embodiment showing the raising and lowering of the spray nozzle in the configuration of the multi-nozzle for supplying CMP slurry according to a preferred embodiment of the present invention.

FIG. 13 is a cross-sectional view showing a cross-sectional view of a multi-nozzle for supplying CMP slurry in a state in which the tube, fixed seal member, and injection nozzle are combined according to a preferred embodiment of the present invention.

FIG. 14 is a perspective view showing a slurry mixing unit mounted on a multi-nozzle for supplying CMP slurry according to a preferred embodiment of the present invention.

### DETAILED DESCRIPTION OF THE EMBODIMENTS

Hereinafter, with reference to the attached drawings, the multi-nozzle for supplying CMP slurry 1 according to an embodiment of the present invention will be described in detail. First of all, it should be noted that in the drawings, identical components or parts are indicated by the same reference numerals whenever possible. In describing the present invention, detailed descriptions of related known functions or configurations are omitted in order to not obscure the gist of the present invention.

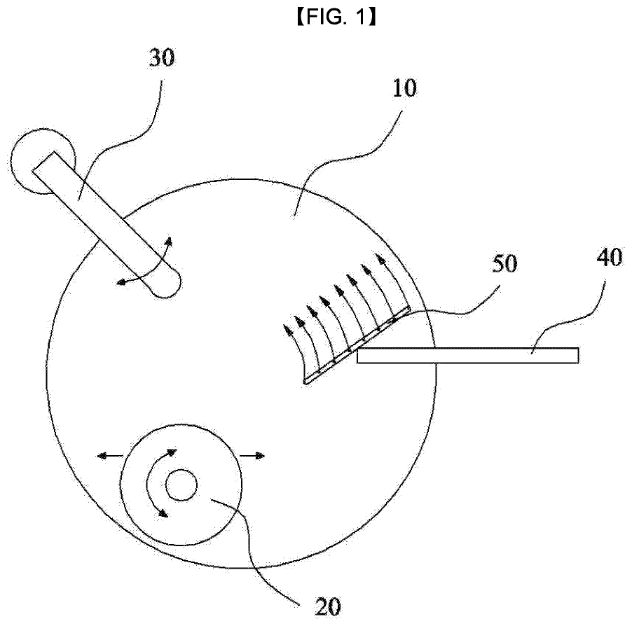

Referring to FIG. 1, 2 or 3, the multi-nozzle for supplying CMP slurry 1 according to an embodiment of the present invention can include a platen, which is a rotary table-shaped body, a pad for performing polishing, a wafer carrier that exerts a force that presses the wafer vertically, a conditioner that removes polishing residues and restores the dull pad to its original state, and a slurry supply device that supplies the slurry, and is formed in a slurry supply device among the configurations of CMP equipment that performs a chemical mechanical polishing (CMP) process, and sprays slurry or deionized water onto the pad. Broadly, it consists of a fitting unit 100, a buffer tank unit 200, a tube 300, and a spray nozzle unit 400.

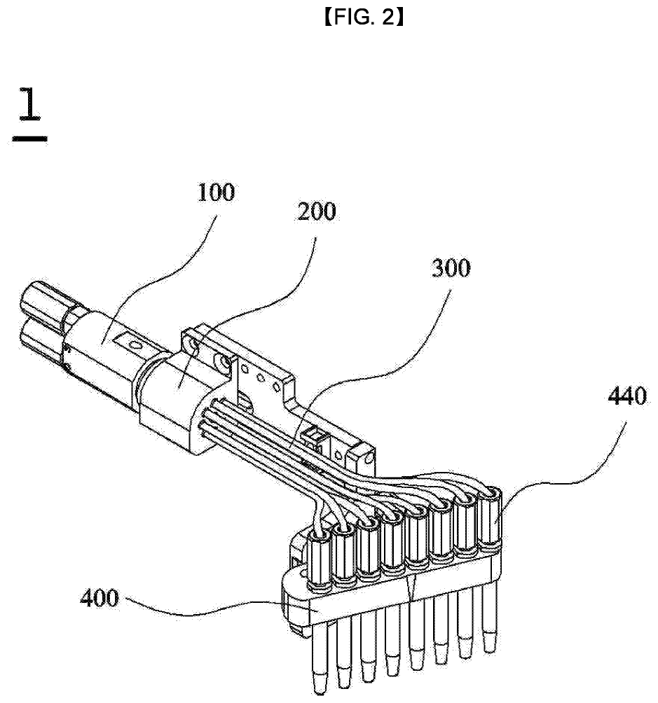

First, the fitting unit 100 will be described. As shown in FIG. 2, 3 or 4, the fitting unit is an element that is connected to each external slurry supply unit and deionized water supply unit to receive slurry or deionized water depending on the process and allows movement to the buffer tank unit 200, which will be described later, and can include a slurry supply line 110, a deionized water supply line 120, a first discharge line 130, and a backflow prevention check valve 140.

The slurry supply line 110 is a type of conduit through which slurry moves, and is formed inward from the end of the fitting unit 100, its end is connected to the slurry supply unit, and its tip is connected to the first discharge line 130, which is branched into a Y shape and will be described later.

The deionized water supply line 120 is a conduit through which deionized water moves, and is formed inward from the end of the fitting unit 100 separately from the slurry supply line 110, its end is connected to the deionized water supply unit, and its tip is connected to the first discharge line (130).

The first discharge line 130 is an element that is connected to the slurry supply line 110 and the deionized water supply line 120, respectively, and through which slurry or deionized water moves depending on the process, and its end is preferably branched into a Y shape and connected to the slurry supply line 110 and the deionized water supply line 120, respectively.

The backflow prevention check valve 140 is an element provided in the deionized water supply line 120, and serves to prevent the slurry supplied through the slurry supply line 110 from flowing back toward the deionized water supply line 120 in the process of moving the slurry toward the buffer tank unit 200 through the first discharge line 130.

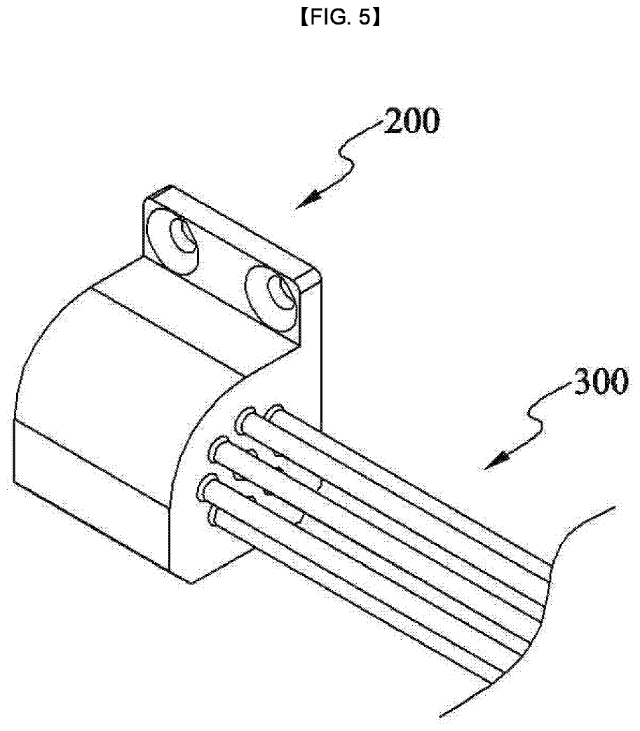

At this time, the backflow prevention check valve 140 is preferably formed to be open in the direction in which deionized water moves (from left to right with respect to FIG. 5) and closed in the reverse direction.

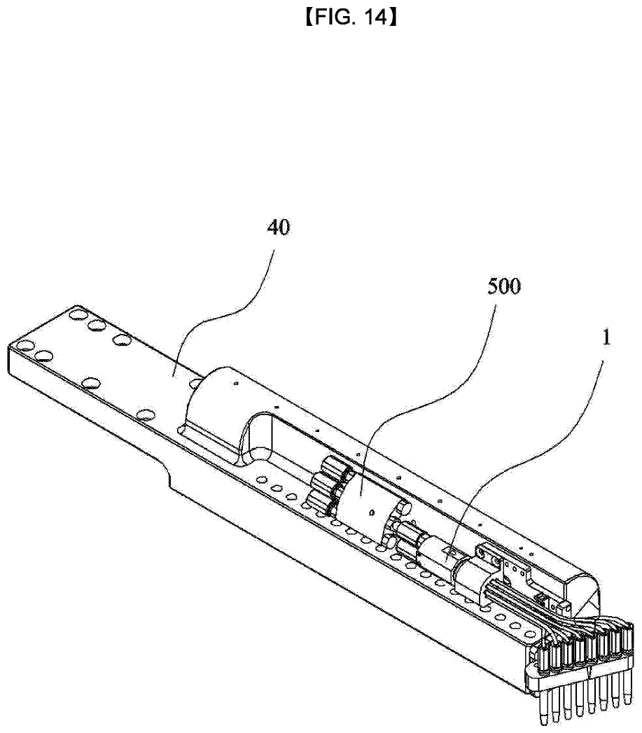

Meanwhile, as shown in FIG. 14, a slurry mixing unit 500 with a plurality of transfer conduits formed inside is formed between the slurry supply unit and the slurry supply line, making it possible to mix and supply slurries with different components.

Next, the buffer tank unit 200 will be described. As shown in FIG. 2, 5 or 6, the buffer tank unit 200 is a component that is coupled to the tip of the fitting unit 100 and uniformly distributes and discharges slurry or deionized water toward the tube 300, which will be described later, and can include a cover member 210, a distribution housing 220, a mesh plate 230, and a connection nipple 240.

The cover member 210 is a type of cover that is coupled and fixed to the front side of the connection plate 410, which will be described later, and a space in which the distribution housing 220 and the mesh plate 230, which will be described later, are seated is formed on the inside, and an insertion hole (not shown) into which a plurality of the tubes 300 are inserted is perforated at the tip.

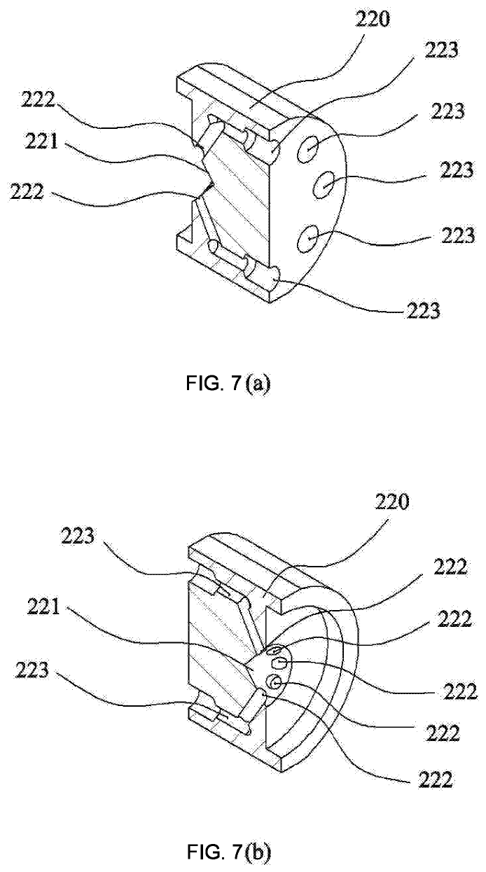

As shown in FIG. 7(a), 7(b) or 8, the distribution housing 220 is an element that is located in a space formed inside the cover member 210 and uniformly distributes the slurry or deionized water moved from the first discharge line 130 to each tube 300, and can include a fluid inlet groove 221, a fluid transfer hole 222, and a second discharge line 223.

The fluid inlet groove 221 is an element that is recessed into a cone-shaped groove in the tip direction at the inner center of the distal end of the distribution housing 220, and through the inclined structure made of a curved surface, the angle of fluid movement into the fluid transfer hole 222, which will be described later, is gentler than when it is formed in a cylindrical or prismatic shape, so the deviation in hydraulic pressure and flow rate can be reduced, making it possible to move slurry or deionized water to each tube 200 at a uniform flow rate.

The fluid transfer hole 222 is a flow path hole formed with a plurality of perforations around the surface of the fluid inlet groove 221 to guide the movement of slurry or deionized water supplied through the fluid inlet groove 221 to the second discharge line 223, which will be described later, and due to the nature of the shape of the fluid transfer hole 222 and the fluid inlet groove 221, they are formed to be inclined at a predetermined angle and are connected to the second discharge line 223, which will be described later.

The second discharge line 223 is an element that is connected to each fluid transfer hole 222 and guides the movement of slurry or deionized water supplied through the fluid transfer hole 222 toward the tube 300, and it is preferable that the fluid transfer holes 222 and the second discharge lines 223 are formed in the same number.

Meanwhile, the second discharge line 223 is arranged in a circle around the horizontal axis of the distribution housing 220 such that the flow rate, hydraulic pressure, and flow rate of the slurry or ionized water supplied to each of the tubes 300 are guided to be moved in a uniform state.

The mesh plate 230 is an element located between the fitting unit 100 and the distribution housing 200, and slows the flow rate of the supplied slurry, guides the slurry to move uniformly to each fluid transfer hole 222 by spreading the slurry with a mesh net is formed in the center, and filter out foreign substances contained in the slurry, preventing hardening, clogging, etc. from occurring in components of the conduit structure such as the tube 300 or the spray nozzle 440, which will be described later.

Next, the tube 300 will be described. As shown in FIG. 2, 5 or 6, the tube 300 is a conduit whose end is connected to the second discharge line 223 and its tip is exposed to the outside through an insertion hole (not shown) formed at the tip of the buffer tank unit 200, thereby moving the slurry or ionized water to the spray nozzle unit 400, and for close connection with the second discharge line 223, the tube 300 and the second discharge line 223 are preferably connected through a connection nipple 240 with a conduit formed on the inside.

Meanwhile, the tube 300 is preferably formed of a Tygon tube whose inner surface is coated to prevent slurry from depositing or hardening.

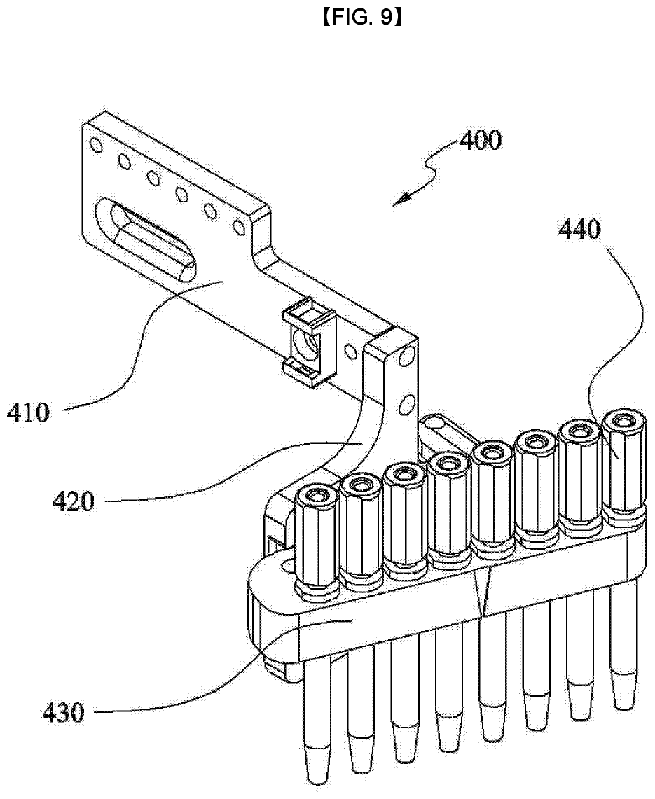

Next, the spray nozzle unit 400 will be described. As shown in FIG. 9, 10, 11(a) or 11(b), the spray nozzle unit 400 is a component connected to each of the tubes 300 to supply slurry or ionized water to the polishing pad, and can include a connection plate 410, a base plate 420, a nozzle block 430, and a spray nozzle 440.

The connection plate 410 is an element formed long in the longitudinal direction, and the buffer tank unit 200 is coupled to its front, and a slurry supply arm 40 is coupled to its rear, and a base plate 420, which will be described later, is coupled to its tip.

The base plate 420 is an element coupled to the connection plate 410 in an orthogonal relationship, and is coupled to a hinge portion 431 and a fixing member 435, which will be described later, respectively, and supports the nozzle block 430, which will be described later.

Meanwhile, a groove-shaped bumper groove 421 is recessed on the side of the base plate 420, and when the rotation block member 432 rotates to its maximum about the hinge portion 431, a bumper stopper 436, which will be described later, is inserted and supported to prevent impact.

Further, a lifting guide groove 422 is perforated in the base plate 420 in the vertical direction.

Meanwhile, the lifting protrusion 431a, which will be described later, is inserted into the lifting guide groove 422 and moves in the up and down directions to enable the hinge portion 431 to move up and down, thereby allowing the height of the spray nozzle 440 to be adjusted.

The nozzle block 430 is an element rotatably coupled to the tip of the base plate 420, the angle of which is adjusted according to the operator's manipulation, and the spray nozzle is seated on it. The nozzle block 430 can includes a hinge portion 431, a rotation block member 432, a fixing member 435, and a bumper stopper 436.

The hinge portion 431 is a component coupled to the tip of the base plate 420 and hinged to the nozzle block 430, and serves as a rotation axis of the nozzle block 430.

Meanwhile, a lifting protrusion 431a is formed at the end of the hinge portion 431 to protrude and is inserted into the lifting guide groove, and fixed and released according to the operator's operation, thereby allowing the height of the hinge portion 431 to be adjusted.

At this time, it is preferable that the lifting protrusion 431a is formed of a bolt fastening type such that it can be easily fixed and released to the lifting guide groove 422.

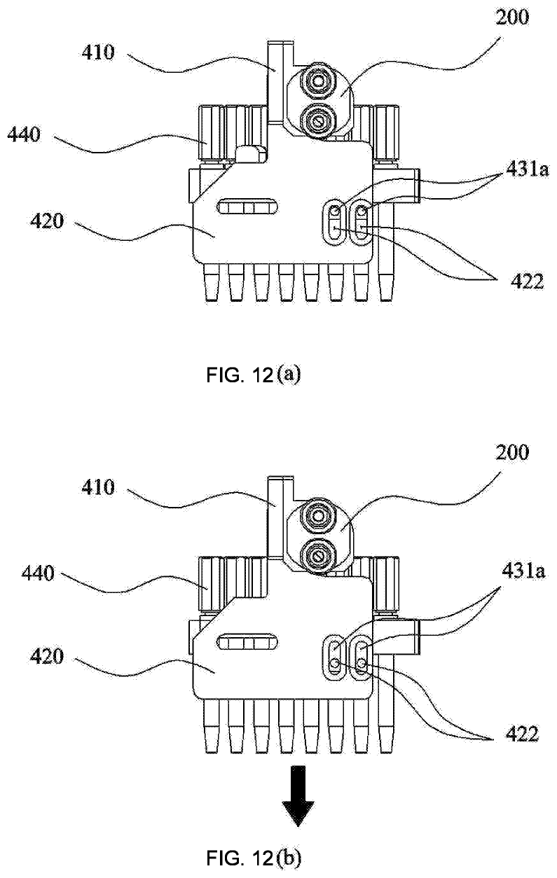

As shown in FIGS. 12(a) and 12(b), the rotation block member 432 is an element that is coupled to the hinge portion 431 and rotates around the hinge portion 431, and whose position is fixed by a fixing member 435, which will be described later, and it has a rotation range from a minimum of 0° to a maximum of 35° on the plane depending on the insertion position of the fixing member 435 inserted into the plurality of angle adjustment holes 433, which will be described later.

Meanwhile, a plurality of angle adjustment holes 433 spaced apart from each other at predetermined intervals are perforated in the rotation block member 432 by inserting a fixing protrusion (not shown) of the fixing member 435 to fix the position of the rotation block member 432, and separately from the angle adjustment holes 433, a plurality of spray nozzle seating holes 434 into which the spray nozzle 440 is inserted and fixed are perforated.

The fixing member 435 is a component formed on the upper side of the base plate 420 to be axis rotatable, and a fixing protrusion (not shown) protruding downward is formed at the lower end of the fixing member, allowing the angle of the rotation block member 432 to be adjusted according to the position of the angle adjustment holes 433 into which the fixing protrusion (not shown) is inserted.

The bumper stopper 436 is an element formed in a curved shape on the side of the rotation block member 432, and when the rotation block member 432 reaches its maximum rotation in the process of rotating around the hinge portion 431, it is inserted into the bumper groove 421 to minimize impact.

The spray nozzle 440 is a component that is connected to the tube 300 and spray slurry or deionized water supplied through the tube 300 onto the pad, and when inserted into the injection nozzle seating holes 434, the spray position can be adjusted by the rotation block member 432.

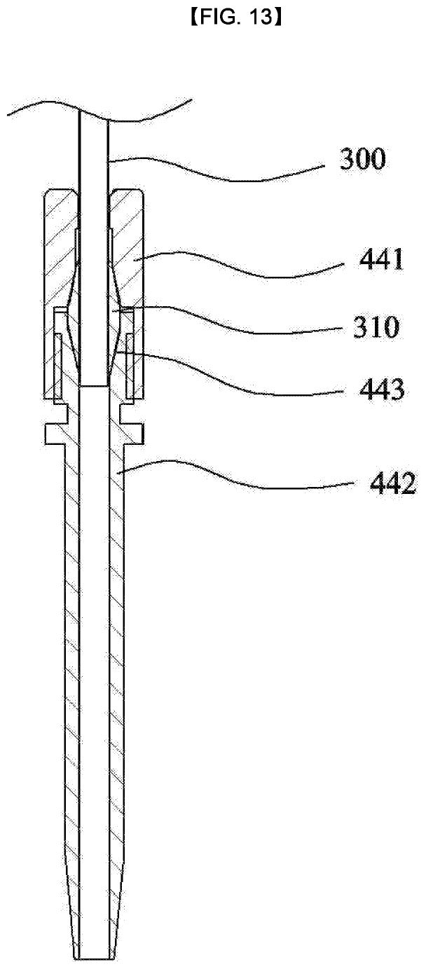

Meanwhile, as shown in FIG. 13, the spray nozzle 440 can include a fitting head 441 into which the tube 300 is inserted, a nozzle tube 442 into which slurry or deionized water is sprayed, and a diamond-shaped coupling groove 443 into which a fixing seal member 310, which will be described later, is inserted and fixed to the inner surface of the fitting head 441.

Meanwhile, a diamond-shaped fixing seal member 310 in surface contact with the outer surface of the tube 300 is provided on the outer surface of the tube 300.

The fixing seal member 310 is inserted into the coupling groove 443 in the process of partially inserting the tip of the tube 300 into the spray nozzle 400, and the fixing seal member 310 inserted into the coupling groove 443 is in close contact with the coupling groove 443 and pressurizes the outer surface of the tube 300 to prevent the tube 300 from being arbitrarily separated from the spray nozzle 400.

Meanwhile, considering the cross-sectional area of the commonly used pad 10, the number of spray nozzles 440 is preferably formed as eight. Moreover, it is preferable that the fluid transfer hole 222, the second discharge line 223, the tube 300, and the spray nozzle seating hole 434 are formed in eight numbers in accordance with the number of spray nozzles 440.

Meanwhile, in order to check whether a constant hydraulic pressure of the slurry supplied through the multi-nozzle for supplying CMP slurry 1 of the present invention is maintained, a pressure sensor is provided in the supply tube connected to the slurry supply unit.

When the slurry hardens or a pressure deviation occurs due to foreign substances in any one of the fitting unit 100, the buffer tank unit 200, the tube 300, or the spray nozzle unit 400, it is possible to respond quickly when hardening or clogging occurs by detecting this with the pressure sensor and transmitting a detection signal to a control room.

Optimal embodiments are disclosed in the drawings and specifications. Although specific terms are used herein, they are used only for the purpose of describing the present invention and are not used to limit the scope of the present invention described in the meaning or claims. Therefore, those skilled in the art will understand that various modifications and other equivalent embodiments are possible therefrom. Therefore, the true technical protection scope of the present invention should be determined by the technical spirit of the attached patent claims.

<Description of Symbols>

```
    1: Multi-nozzle for supplying CMP slurry
  100: Fitting unit
  110: Slurry supply line
  120: Deionized water supply line
```

| | |
|---|---|
| 130: First discharge line | 140: Backflow prevention check valve |

200: Buffer tank unit

| | |
|---|---|
| 210: Cover member | 220: Distribution housing |
| 221: Fluid inlet groove | 222: Fluid transfer hole |
| 223: Second discharge line | 230: Mesh plate |

240: Connection nipple

| | |
|---|---|
| 300: Tube | 310: Fixing seal member |

400: Spray nozzle unit

| | |
|---|---|
| 410: Connection plate | 420: Base plate |
| 421: bumper groove | 422: Lifting guide groove |
| 430: Nozzle block | 431: Hinge portion |
| 431a: Lifting protrusion | 432: Rotation block member |
| 433: Angle adjustment hole | 434: Spray nozzle seating hole |
| 435: Fixing member | 436: Bumper stopper |
| 440: Spray nozzle | 441: Fitting head |
| 442: Nozzle tube | 443: Coupling groove |

```
  450: Pointer jig
  500: Slurry mixing unit
```

What is claimed is:

1. Multi-nozzle for supplying CMP slurry 1, comprising:
a fitting unit 100 connected to supply a slurry stored in a slurry supply unit and a deionized water stored in a deionized water supply unit;
a buffer tank unit 200 coupled to the tip of the fitting unit 100, which uniformly distributes the slurry or deionized water and discharges it through a plurality of lines;
a plurality of tubes 300 connected to the tip of the buffer tank unit 200; and
a spray nozzle unit 400 connected to each of the tubes 300 to supply the slurry or deionized water to a polishing pad.

2. The multi-nozzle of claim 1, wherein the fitting unit 100 comprises:
a slurry supply line 110 through which the slurry is supplied and a deionized water supply line 120 through which the deionized water is supplied; and
a first discharge line 130 connected to the slurry supply line 110 and the deionized water supply line 120.

3. The multi-nozzle of claim 2, wherein the deionized water supply line 120 comprises a backflow prevention check valve 140 to prevent the slurry supplied through the slurry supply line 110 from flowing back toward the deionized water supply line 120.

4. The multi-nozzle of claim 1, wherein the buffer tank unit 200 comprises:
a cover member 210 with a space formed on the inside; and
a distribution housing 220 that is seated in the space of the cover member 210 to distribute the slurry or deionized water.

5. The multi-nozzle of claim 4, wherein the distribution housing 220 comprises:
a cone-shaped fluid inlet groove 221 at the center of its end;
a plurality of fluid transfer holes 222 formed around the surface of the fluid inlet groove 221; and
a plurality of second discharge lines 223 connected to each of the fluid transfer holes 222.

6. The multi-nozzle of claim 4, wherein between the fitting unit 100 and the distribution housing 220, comprises a mesh plate 230 to spread the slurry or filter out foreign substances contained in the slurry in the process of supplying the slurry to the distribution housing 220 through the slurry supply line 110 and the first discharge line 130.

7. The multi-nozzle of claim 5, wherein the second discharge line 223 is arranged in a circular shape around the horizontal axis of the distribution housing 220.

8. The multi-nozzle of claim 5, wherein the tube 300 is connected to the second discharge line 223, and the tube 300 and the second discharge line 223 are connected through a connection nipple 240.

9. The multi-nozzle of claim 1, wherein the spray nozzle unit 400 comprises:
a connection plate 410 coupled to the buffer tank unit 200;
a base plate 420 coupled to the tip of the connection plate 410;
a nozzle block 430 whose angle is adjusted according to an operator's operation at the tip of the base plate 420; and
a spray nozzle 440 coupled to the nozzle block 430 and connected to the tube 300.

10. The multi-nozzle of claim 9, wherein the nozzle block 430 comprises:
a hinge portion 431 formed on the base plate 420;
a rotation block member 432 that is coupled to the hinge portion 431 and rotates around the hinge portion 431, and is formed with a plurality of angle adjustment holes 433 and a plurality of spray nozzle seating holes 434, respectively; and
a fixing member 435 capable of adjusting the angle of the rotation block member 432 according to the angle adjustment hole 433 that is rotatably formed and inserted into the base plate 420.

11. The multi-nozzle of claim 9, wherein the spray nozzle 440 comprises:
a fitting head 441 into which the tube 300 is inserted; and
a nozzle tube 442 through which the slurry or deionized water is sprayed.

12. The multi-nozzle of claim 9, wherein the spray nozzle 440 is formed in eight pieces.

13. The multi-nozzle of claim 10, wherein on the side of the base plate 420 a bumper groove 421 is recessed, and on the side of the rotation block member 432, in the process of rotating the rotation block member 432 around the hinge portion 431, when the maximum rotation of the rotation block member 432 is achieved, a bumper stopper 436 is formed to be inserted into the bumper groove 421.

14. The multi-nozzle of claim 10, wherein a lifting protrusion 431a is formed protruding at the end of the hinge portion 431, and a lifting guide groove 422 is perforated in the base plate 420 such that the lifting protrusion 431a is inserted and the hinge portion 431 is raised or lowered.

15. The multi-nozzle of claim 11, wherein a diamond-shaped fixing seal member 310 is provided on the outer surface of the tube 300, and a diamond-shaped coupling groove 443 is formed on the inner surface of the fitting head 441 such that the fixing seal member 310 is inserted and fixed.

16. The multi-nozzle of claim 1, wherein at the end of the fitting unit 100 a slurry mixing unit 500 is connected to the slurry supply line 110 to mix and supply slurries with different components.

17. The multi-nozzle of claim 1, wherein a pressure sensor is provided in a supply tube connected to the slurry supply unit, and when any one of the fitting unit 100, the buffer tank unit 200, the tube 300, or the spray nozzle unit 400 is clogged due to hardened slurry or foreign substances, the pressure sensor detects pressure deviation and transmits a detection signal to a control room.

18. A semiconductor CMP equipment having a multi-nozzle 1 for supplying CMP slurry, the multi-nozzle 1 comprising:
a buffer tank unit 200 that uniformly distributes the slurry or deionized water and discharges it through a plurality of lines; and
a spray nozzle unit 400 connected to the buffer tank unit 200 to spray divided slurry or deionized water onto a polishing pad.
